(19) United States
(12) Patent Application Publication
(10) Pub. No.: US 2023/0340370 A1
(43) Pub. Date: Oct. 26, 2023

(54) Composition, Its Use And A Process For Removing Post-Etch Residues

(71) Applicant: BASF SE, Ludwigshafen am Rhein (DE)

(72) Inventors: Andreas KLIPP, Ludwigshafen (DE); Chia Wei CHANG, Taoyuan (TW); Meng Ju YU, Taoyuan (TW); Jhih Jheng KE, Taoyuan (TW); Cheng Shun CHEN, Taoyuan (TW)

(21) Appl. No.: 18/042,606

(22) PCT Filed: Aug. 16, 2021
(86) PCT No.: PCT/EP2021/072719

§ 371 Date: Feb. 23, 2023

(30) Foreign Application Priority Data
Aug. 25, 2020 (EP) 20192699.5

(51) Int. Cl. C11D 3/43; C11D 3/30; C11D 3/04; C11D 3/39; C11D 11/00

(52) U.S. Cl. CPC C11D 3/3927; C11D 3/042; C11D 3/30; C11D 3/43; C11D 11/0047

(57) ABSTRACT

Disclosed herein is a composition for removing post-etch residues in the presence of a layer comprising silicon and a dielectric layer including a silicon oxide, the composition including:
(a) 0.005 to 0.3 % by weight HF;
(b) 0.01 to 1 % by weight of an ammonium fluoride of formula NR^{E}₄F, where R^{E} is H or a C₁ to C₄ alkyl group;
(c) 5 to 30 % by weight of an organic solvent selected from the group consisting of a sulfoxide and a sulfone;
(d) 70 % by weight or more water, and
(e) optionally 0.01 to 1 % by weight of an ammonium compound selected from the group consisting of ammonia and a C₄ to C₂₀ quaternized aliphatic ammonium.

The present invention relates to a composition, its use and a process for removing post-etch residues in the presence of a layer comprising silicon and a dielectric layer comprising a silicon oxide.

### BACKGROUND OF THE INVENTION

Steps of preparing certain microelectronic devices, e.g., integrated circuits, may include removing oxide residues remaining within the recessed patterns opened by etching a layer of amorphous silicon. The patterns in this amorphous silicon layer are usually prepared by dry etching through a photomask that is afterwards removed by ashing. After these dry etching and ashing steps oxide residues remain on the surface and particularly within the patterns of the amorphous silicon layer that need to be removed to avoid any significant impact on the electrical integrity of the integrated circuit.

The main task here is to effectively remove the oxide residues without impacting the amorphous silicon layer itself and a dielectric layer, e.g. a dielectric layer prepared from tetraethyl orthosilicate and therefore often named “TEOS” in the industry, below the amorphous silicon.

For oxide residue removal usually compositions comprising hydrofluoric acid (HF) are used but such compositions show either a good oxide residue removal rate or a low etching rate of the TEOS layer, i.e. the selectivity for oxide residues against TEOS is rather low.

WO 02/004233 A1 discloses a composition for the stripping of photoresist and the cleaning of residues from substrates, and for silicon oxide etch, comprising from 0.01 to 10 % by weight of one or more fluoride compounds, from 10 to 95 % by weight of a sulfoxide or sulfone solvent, and from about 20 to 50 % by weight water. However, this composition is unable to effectively remove thermal oxide residues.

WO 2010/113616 discloses a solution for etching a silicon oxide film, the solution containing hydrofluoric acid, ammonium fluoride, an acid having a pKₐ higher than that of hydrofluoric acid, a base having a pKₐ higher than that of ammonia, and water.

WO 2005/057281 A2 discloses an aqueous-based composition and process for removing photoresist, bottom anti-reflective coating (BARC) material, and/or gap fill material from a substrate having such material(s) thereon. The aqueous-based composition includes a fluoride source, at least one organic amine, at least one organic solvent, water, and optionally a chelating agent and/or surfactant.

However, the state-of-the-art solutions are not able to fulfil all requirements since they have at least one of the following deficiencies:
(a) a too high dielectric silicon oxide etching, particularly TEOS etching, as illustred in FIG. 2a;
(b) a bad side wall etch-residue cleaning as illustrated in FIG. 2b.

It is therefore an object of the present invention to ensure a good etch-residue removal rate in combination with a low dielectric etching rate, particularly TEOS etching rate. Furthermore, it is an object of the invention to develop a composition that shows an increased etch-residue to dielectric selectivity.

### SUMMARY OF THE INVENTION

It has now been found that the use of an aqueous composition comprising HF, an ammonium fluoride, and a particular solvent is capable of removing post-etch residues comprising silicon oxide against elemental silicon and a dielectric material, particularly against amorphous silicon and TEOS.

Therefore, one embodiment of the present invention is a composition for removing post-etch residues in the presence of a layer comprising silicon and a dielectric layer comprising a silicon oxide, the composition comprising or essentially consisting of:
(a) 0.005 to 0.3 % by weight HF;
(b) 0.01 to 1 % by weight of an ammonium fluoride of formula NR^{E}₄F, wherein R^{E} is H or a C₁ to C₄ alkyl group;
(c) 5 to 30 % by weight of an organic solvent selected from a sulfoxide and a sulfone;
(d) 70 % by weight or more water, and
(e) optionally 0.01 to 1 % by weight of an ammonium compound selected from ammonia and a C₄ to C₂₀ quaternized aliphatic ammonium.

It was particularly surprising that the etching composition according to the invention is suited to allow for a controlled and selective etching of oxidic post-etch-residues while at the same time not or not significantly compromising silicon containing layers and dielectric layers comprising silicon oxide.

It should be emphasized that the compounds in the composition according to the invention may react to form other compounds, particularly component (a), HF, may react with optional component (e), an ammonium compound, if it is ammonia. In this case, depending on the ratio of components (a) and (e), HF may be reduced or even completely neutralized, and additional ammonium fluoride is formed. Therefore, the composition also covers reaction products of the compounds (a) to (e) above.

Another embodiment of the present invention is the use of the compositions described herein for removing post-etch residues in the presence of a layer comprising silicon and a dielectric layer comprising a silicon oxide.

Yet another embodiment of the present invention is a process of removing post-etch residues in the presence of a silicon layer comprising silicon and a dielectric layer comprising a silicon oxide, the process comprising:
(a) providing a microelectronic device comprising a surface that comprises the post-etch residues, the silicon layer and the dielectric layer,
(b) providing a composition as describe herein, and
(c) contacting the surface with the composition for a time and at a temperature effective to remove the post-etch residues without damaging the silicon layer and the dielectric layer.

### BRIEF DESCRIPTION OF THE DRAWING

FIG. 1 schematically shows the substrate before dry-etching and PR removal, (a) before and (b) after the post-etch residue removal according to the invention.

FIG. 2 schematically shows the substrate before dry-etching and PR removal, before and after the post-etch residue removal using prior art residue removal compositions with (a) high HF concentrations; and (b) with low HF concentrations.

### DETAILED DESCRIPTION OF THE INVENTION

The purpose of the composition is etching silicon oxide residues against an elemental silicon layer and, in particular, a silicon oxide containing dielectric layer. Since both the post-etch residues and the dielectric layer comprise or consist of a silicon oxide, it is particularly challenging to get high etch rates for the silicon oxide residues and sufficiently low etch rates for the dielectric layer, particularly if the dielectric layer comprises or consists of TEOS.

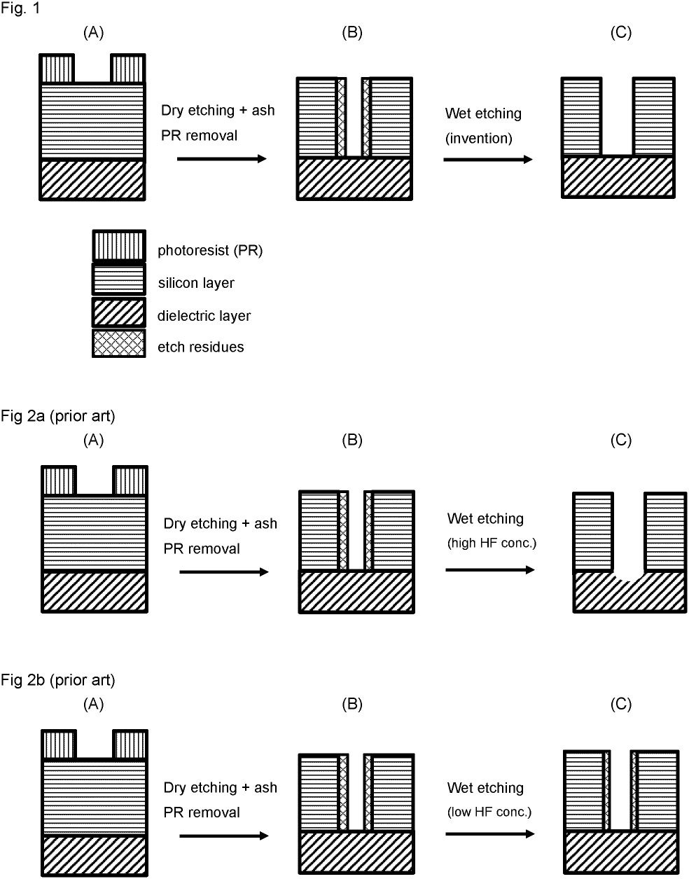

As schematically shown in FIG. 1 the etch residue removal composition is able to remove the oxide residues after a dry-etching step without jeopardizing an underlying silicon oxide based dielectric layer. In contrast, the prior art compositions either suffer from an over-etching of the dielectric layer if high HF concentrations are used (FIG. 2a) or insufficient removal of the oxide residues if low HF concentrations are used (FIG. 2b). Only with the specific composition comprising or essentially consisting of
(a) 0.005 to 0.3 % by weight HF;
(b) 0.01 to 1 % by weight of an ammonium fluoride of formula NR^{E}₄F, wherein R^{E} is H or a C₁ to C₄ alkyl group;
(c) 5 to 30 % by weight of an organic solvent selected from a sulfoxide and a sulfone;
(d) 70 % by weight or more water, and
(e) optionally 0.01 to 1 % by weight of an ammonium compound selected from ammonia and a C₄ to C₂₀ quaternized aliphatic ammonium hydroxide,
a sufficiently low dielectric etching in combination with a sufficiently high removal rate of the oxide residues can be achieved.

### Etchants

At least two etchants are present in the etching composition according to the invention, hydrogen fluoride and an ammonium fluoride of formula NR^{E}₄F.

### Hydrogen Fluoride

Hydrogen fluoride may be used in an amount of from about 0.005 to about 0.3 % by weight, preferably of from about 0.008 to about 0.2 % by weight, more preferably of from about 0.01 to about 0.1 % by weight, most preferably of from about 0.01 to about 0.05 % by weight, based on the total weight of the composition.

Hydrogen fluoride may be present in the etching composition in an amount of from about 0.01 to about 0.6 mol/l, preferably of from about 0.01 to about 0.5 mol/l, more preferably of from about 0.015 to about 0.3 mol/l, most preferably of from about 0.02 to about 0.15 mol/l.

### Ammonium Fluoride

The ammonium fluoride NR^{E}₄F is present in an amount of from about 0.01 to about 1 % by weight, preferably from about 0.1 to about 0.8 % by weight, most preferably from about 0.2 to about 0.6 % by weight.

R^{E} may be H or a C₁ to C₄ alkyl group, preferably H, methyl, ethyl or propyl, more preferably H, methyl or ethyl, even more preferably H or methyl, most preferably H.

In a preferred embodiment the etchant comprises a combination of NH₄F and N(CH₃)₄F, preferably in a mass ratio of from 0.05 to 1, particularly from 0.1 to 0.5.

The etching compositions according to the invention comprising a combination of hydrogen fluoride and ammonium fluoride as the etchant have shown a stable and reproducible controlled selective etch rate for etching oxide residues in the presence of a dielectric layer, particularly a TEOS layer.

Most preferably the etchant consists of a combination of hydrogen fluoride and ammonium fluoride NR^{E}₄F, i.e. no further etchants besides hydrogen fluoride and ammonium fluoride NR^{E}₄F are present in the etching composition.

In a preferred embodiment the etchant consists of a combination of hydrogen fluoride and ammonium fluoride in a mass ratio of from 0.005 to 1, preferably of from 0.01 to 0.5, most preferably of from 0.02 to 0.2.

Compositions according to the invention comprising the etchant in the here defined preferred total amounts have shown a superior balance of acceptable etch rate, in particular for etch residues comprising silicon oxide, and etch rate selectivity, in particular in the presence of a layer comprising or consisting of a dielectric, such as but not limited to TEOS.

### Organic Solvent

The etching composition according to the invention further comprises from about 5 to about 30 % by weight of an organic solvent selected from a sulfoxide and a sulfone.

Preferably the organic solvent may be present in the etching composition in an amount of from about 8 to about 27 % by weight, more preferably of from about 10 to about 25 % by weight, even more preferably of from about 12 to about 23 % by weight, most preferably from about 15 to about 20 % by weight.

Preferred sulfoxides are compounds of formula

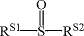

wherein R^{S1} and R^{S2} are independently selected from a C₁ to C₄ alkyl or R^{S1} and R^{S2} together form an C₄ or C₅ alkanediyl group to form 5 or 6 membered saturated cyclic ring system.

Suitable sulfoxide solvents include the following and mixtures thereof: Dimethyl sulfoxide (DMSO), dipropylsulfoxide, diethylsulfoxide, methylethylsulfoxide, diphenylsulfoxide, methylphenylsulfoxide, 1, 1′-dihydroxyphenyl sulfoxide and the like.

Preferred sulfones are compounds of formula

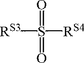

wherein R^{S3} and R^{S4} are independently selected from a C₁ to C₄ alkyl or R^{S3} and R^{S4} together form an C₄ or C₅ alkanediyl group to form 5 or 6 membered saturated cyclic ring system.

Suitable sulfone solvents include the following and mixtures thereof dimethylsulfone, diethylsulfone, 2,3,4,5-tetrahydrothiophene-1,1-dioxide (also referred to as sulfolane) and the like.

The solvent should be water miscible to provide a homogenous solution. The term “water-miscible organic solvent” in the context of the present invention preferably means that an organic solvent fulfilling this requirement is miscible with water at least in a 1:1 weight ratio at 20° C. and ambient pressure.

In a preferred embodiment the organic solvent is selected from the group consisting of DMSO, sulfolane and mixtures thereof. The most preferred organic solvent is DMSO.

### Ammonium Hydroxide Compound

To further enhance selectivity the composition according to the present invention comprises ammonia or a C₄ to C₂₀ aliphatic quaternized ammonium hydroxide compound in an amount of from 0.01 to 1 % by weight as an optional component.

In a first embodiment ammonia is added to the etching composition, preferably in the form of ammonia water.

Preferably ammonia may be added in an amount of from about 0.03 to 2 % by weight, more preferably from 0.05 to 1.5 % by weight, even more preferably from 0.1 to about 1 % by weight, most preferably from 0.15 to 0.5 % by weight.

Preferably the mass ratio of ammonia to the etchant, particularly HF, is of from 0.2 to 4, more preferably of from 0.5 to 2.

In a second embodiment a C₄ to C₂₀ quaternized aliphatic ammonium compound is added to the etching composition.

Such C₄ to C₂₀ quaternized aliphatic ammonium compounds comprise the following formula

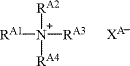

wherein R^{A1} R^{A2}, R^{A3}, and R^{A4} are the same or different and independently selected from a C₁ to C₁₀ alkyl, wherein the sum of carbon atoms within R^{A1}, R^{A2}, R^{A3}, and R^{A4} are 20 or less. Preferably R^{A1}, R^{A2}, R^{A3}, and R^{A4} are independently selected from a C₁ to C₆ alkyl, most preferably from a C₁ to C₄ alkyl, and X^{A} is a counter ion such as but not limited to sulfate, chloride and hydroxide, preferably hydroxide.

Preferred C₄ to C₂₀ quaternized aliphatic ammonium compound are selected from tetramethyl ammonium hydroxide (TMAH), tetraethyl ammonium hydroxide (TEAH).

The C₄ to C₂₀ quaternized aliphatic ammonium compound may be added in an amount of from about 0.03 to 2 % by weight, more preferably from 0.05 to 1.5 % by weight, even more preferably from 0.1 to about 1 % by weight, most preferably from 0.15 to 0.5 % by weight.

Preferably the molar ratio of the C₄ to C₂₀ quaternized aliphatic ammonium compound to the etchant, particularly HF, is of from 0.3 to 2, more preferably of from 0.5 to 1.

### Surfactants

The composition may also further comprise one or more surfactants as an optional component.

Preferred surfactants are selected from the group consisting of
(i) anionic surfactants, preferably selected from the group consisting of ammonium lauryl sulfate, a C₆ to C₂₀ carboxylic acid or its salts, preferably a C₆ to C₁₂ aliphatic carboxylic acid such as but not limited to octanoic acid; fluorosurfactants, preferably selected from the group consisting of perfluorinated alkylsulfonamide salts (preferably perfluorinated, N-substituted alkylsulfonamide ammonium salts, PNAAS), perfluorooctanesulfonate, perfluorobutane-sulfonate, perfluorononanoate and perfluorooctanoate; alkyl-aryl ether phosphates and alkyl ether phosphates;
(ii) cationic surfactants, preferably selected from the group consisting of a C₆ to C₂₀ alkylamine or its salts, a quaternary C₆ to C₃₀ ammonium compound, preferably a quaternary C₆ to C₃₀ alkyl ammonium compound. Preferred cationic surfactants are selected from the group consisting of alkyltrimethyl ammonium compounds like cetyltrimethylammonium chloride, N-oleyl-1,3-propanediamine, octylamine, dimethyldioctadecylammonium chloride, cetylpyridinium chloride, cetalkonium chloride, hydroxyethyl laurdimoniumchloride, and hexadecyltrimethyl ammoniumchloride;
(iii) zwitterionic surfactants, preferably selected from the group consisting of (3-[(3-cholamidopropyl)dimethylammonio]-1-propanesulfonate) (“CHAPS”), cocamidopropyl hydroxysultaine (CAS RN 68139-30-0), {[3-(dodecanoylamino)propyl](dimethyl)-ammonio}acetate, phosphatidylserine, phosphatidylethanolamine, phosphatidylcholine, and
(iv) non-ionic surfactants, preferably selected from the group consisting of glucoside alkyl ethers, glycerol alkyl ethers, cocamide ethanolamines and lauryldimethylaminoxide.

More preferred surfactants in compositions according to the invention are or comprise perfluorinated, N-substituted alkylsulfonamide ammonium salts.

Preferred surfactants in compositions according to the invention do not comprise metals or metal ions.

In a preferred embodiment the composition comprises a combination of anionic surfactant, preferably a C₆ to C₂₀ carboxylic acid or their salts, most preferably a C₆ to C₁₂ aliphatic carboxylic acid, and a cationic surfactant, preferably a C₆ to C₃₀ alkylamine or its salts, a C₆ to C₃₀ quaternary ammonium compound, most preferably a quaternary C₆ to C₃₀ alkyl ammonium compound.

### Composition

The compositions according to the present inventions are water-based compositions, i.e. water forms the major part of at last 70% by weight of the composition. Preferably the amount of water present in the composition is 72 % by weight or more, more preferably 75 % by weight or more, even more preferably 78 % by weight or more, most preferably 80 % by weight or more.

In a preferred embodiment the pH of the etching composition is of from 1 to 7, particularly of from 2 to 6, most particularly from 3 to 5.

In a first particular embodiment the composition comprises or consists of
(a) 0.01 to 0.3 % by weight HF;
(b) 0.1 to 1% by weight of the ammonium fluoride of formula NR^{E}₄F, wherein R^{E} is H, methyl or ethyl;
(c) 5 to 30 % by weight of the organic solvent;
(d) 70 % by weight or more water;
(e) optionally 0.05 to 0.5 % by weight of an ammonium compound selected from ammonia and a C₄ to C₂₀ quaternized aliphatic ammonium; and
(f) optionally 0.001 to 1 % by weight of a surfactant selected from a C₆ to C₂₀ aliphatic amine, a C₆ to C₂₀ aliphatic acid, and a combination thereof.

In a second particular embodiment the composition comprises or consists of
(a) 0.01 to 0.1 % by weight HF;
(b) 0.1 to 0.6 % by weight of the ammonium fluoride of formula NR^{E}₄F, wherein R^{E} is H, methyl or ethyl;
(c) 10 to 25 % by weight of the organic solvent;
(d) 74.3 % by weight or more water;
(e) optionally 0.05 to 0.5 % by weight of an ammonium compound selected from ammonia and a C₄ to C₂₀ quaternized aliphatic ammonium; and
(f) optionally 0.001 to 0.5 % by weight of a surfactant selected from a C₆ to C₂₀ aliphatic amine, a C₆ to C₂₀ aliphatic acid, and a combination thereof.

In a third particular embodiment the composition comprises or consists of
(a) 0.001 to 0.1 % by weight HF;
(b) 0.1 to 0.6 % by weight of the ammonium fluoride of formula NR^{E}₄F, wherein R^{E} is H, methyl or ethyl;
(c) 12 to 23 % by weight of the organic solvent;
(d) 76.3 % by weight or more water as balance to a total of 100 % by weight of the composition in each case;
(e) optionally 0.05 to 0.3 % by weight of an ammonium compound selected from ammonia and a C₄ to C₂₀ quaternized aliphatic ammonium; and
(f) 0.005 to 0.1 % by weight of a surfactant selected from a C₆ to C₂₀ aliphatic amine, a C₆ to C₂₀ aliphatic acid, and a combination thereof.

All percent, ppm or comparable values refer to the weight with respect to the total weight of the respective composition except where otherwise indicated. All % amounts of the components add to 100 % by weight in each case.

### Application

It will be appreciated that it is common practice to make concentrated forms of the compositions to be diluted prior to use. For example, the compositions may be manufactured in a more concentrated form and thereafter diluted with water, at least one oxidizing agent, or other components at the manufacturer, before use, and/or during use. Dilution ratios may be in a range from about 0.1 parts diluent to 1 parts composition concentrate to about 100 parts diluent to 1 part composition concentrate.

The etching composition described herein may be advantageously used for removing post-etch residues in the presence of a silicon layer comprising silicon and a dielectric layer comprising a silicon oxide, particularly TEOS. It may also be advantageously used in a process for the manufacture of a semiconductor device comprising the step of removing silicon oxide residues from a surface of a microelectronic device relative to a silicon oxide based dielectric layer, particularly TEOS.

The etching composition described herein may be advantageously used in a process of removing post-etch residues in the presence of a silicon layer comprising silicon and a dielectric layer comprising a silicon oxide, the process comprising:
(a) providing a microelectronic device comprising a surface that comprises the post-etch residues, the silicon layer and the dielectric layer,
(b) providing a composition as described herein, and
(c) contacting the surface with the composition for a time and at a temperature effective to remove the post-etch residues without damaging the silicon layer and the dielectric layer.

In a preferred embodiment before step (a) above further steps (a1) and (a2) are performed:
(a1) dry etching the silicon layer to form recesses in the silicon layer through a photoresist located on top of the parts of the silicon layer not to be dry etched, and
(a2) removing the photoresist by ashing.

The application of the compositions according to the invention are described in more detail with respect to the structures depicted in FIG. 1 without restricting the invention thereto.

With respect to structure (A), the electronic device structure comprises a silicon layer onto which a patterned photoresist is located. Below the silicon layer there is a dielectric layer.

In structure (A) the silicon layer is opened by dry etching through the photomask. Afterwards, the photomask on top of the silicon layer is removed. The technology of dry etching of a silicon layer is well known in the art and not further described herein.

In many cases residues, particularly sidewall residues, comprising high amount of silicon oxide remain on the surface of the recessed feature. These need to be removed without damaging the silicon layer and particularly the underlying dielectric layer. This is particularly challenging if the dielectric layer is susceptible to fluoride etching like TEOS.

As used herein, “Silicon oxide residues” or “oxide residues” mean residues comprising silicon oxide usually received by dry etching of the layer comprising silicon and the thermal removal of the photomask, i.e. impure silicon oxide including other elements or oxides.

As used herein, “silicon layer” or “layer comprising silicon” means a layer that comprises elemental silicon. The silicon may be amorphous silicon (a-Si), polycrystalline silicon (poly-Si), crystalline silicon, or combinations thereof. Amorphous silicon is preferred.

“Dielectric layer” corresponds to a layer that comprises any sort of silicon oxide used for preparing a dielectric layer, such as but not limited to TEOS, thermal silicon oxide, or carbon doped oxides (CDO) deposited using commercially available precursors such as SiLK™, AURORA™, CORAL™ or BLACK DIAMOND™.

As used herein, the term “TEOS” corresponds to silicon oxide based dielectric materials made by decomposition of tetraethoxy orthosilicate.

As used herein, removing a first material without damaging a second material preferably means that upon applying a composition according to the invention to a substrate comprising or consisting of the first material, in this case SiOₓ, in the presence of one or more substrates comprising or consisting of the second material, in this case particularly a-Si or TEOS, the etch rate of said composition for etching the first material is such that the first material is removed and the etching of the second material sufficiently suppressed not to cause structural damages on the substrate, particularly over-etching of the dielectric material.

As used herein, the term “layer” means a part of a substrate that was separately disposed on the surface of a substrate and has a distinguishable composition with respect to adjacent layers.

All cited documents are incorporated herein by reference.

The following examples shall further illustrate the present invention without restricting the scope of this invention.

### EXAMPLES

The following non-patterned coupons were used as model layers for etch rate determination:
(a) 20 nm amorphous silicon on 5 nm thermal SiO₂ on Silicon for the a-Si etch rate (ER),
(b) 150 nm TEOS on Silicon for the TEOS ER,
(c) 100 nm thermal SiO₂ on Silicon for the SiOₓ residue ER.

The thermal SiO₂ was used to represent the etch rate of the post-etch-residues due to its similarity to etch-residues on patterned substrates.

The following materials were used in electronic grade purity:
NH₄OH (28 %)
TMAH
HF (50 %)
DMSO, Sulfolane
Water (Ultrapure)

All amounts given for the compounds in the composition are absolute amounts, i.e. excluding water, in the overall mixture.

The raw materials were mixed with water according to the weight content described in table 1 at room temperature with no special order of mixing. The formulation was then cooled or heated to the described temperature.

The substrates were etched at 40° C. by dipping the respective coupons into the etching solution according to table 1, washed with water and dried with nitrogen blowing The etching rates were determined by Ellipsometry by comparing the layer thickness before and after etching. Ellipsometry was performed by using an M2000 Elipsometer from Woolam. The etch rates (in Å/min; 1 Å = 0.1 nm) are depicted in table 1.

TABLE 1

| | | | | | | | | | |
|---|---|---|---|---|---|---|---|---|---|
| Etchant | HF [wt%] | 0.11 | 0.11 | 0.11 | 0.11 | 0.11 | 0.11 | 0.11 | 0.11 |
| Solvent [wt%] | Diethylene Glycol Butyl Ether | -- | 10 | -- | -- | -- | -- | -- | -- |
| | DMSO | -- | -- | 10 | -- | -- | -- | -- | -- |
| | sulfolane | -- | -- | -- | 10 | -- | -- | -- | -- |
| | Ethlene glycol | -- | -- | -- | -- | 10 | -- | -- | -- |
| | Glycol | -- | -- | -- | -- | -- | 10 | -- | -- |
| | n-formyl-morpholine | -- | -- | -- | -- | -- | -- | 10 | -- |
| | Dipropylene glycol methyl ether | -- | -- | -- | -- | -- | -- | -- | 10 |
| TEOS ER (Å/min) | | 45 | 11 | 30 | 36 | 19 | 18 | 33 | 20 |
| SiOₓ residue ER (Å/min) | | 10 | 5 | 10 | 10 | 3 | 4 | 8 | 4 |
| a-Si ER (Å/min) | | 0.3 | 0.3 | 0.5 | 0.5 | 0.2 | 0.3 | 0.2 | 0.3 |

1. A composition for removing post-etch residues in the presence of a layer comprising silicon and a dielectric layer comprising a silicon oxide, the composition comprising:
(a) 0.005 to 0.3 % by weight HF;
(b) 0.01 to 1 % by weight of an ammonium fluoride of formula NR^{E}₄F, wherein R^{E} is H or a C₁ to C₄ alkyl group;
(c) 5 to 30 % by weight of an organic solvent selected from the group consisting of a sulfoxide and a sulfone;
(d) 70 % by weight or more water, and
(e) optionally 0.01 to 1 % by weight of an ammonium compound selected from the group consisting of ammonia and a C₄ to C₂₀ quaternized aliphatic ammonium hydroxide.

2. The composition according to claim 1, wherein HF is present in an amount of from 0.01 to 0.1 % by weight.

3. The composition according to claim 1, wherein the ammonium fluoride is present in an amount of from 0.1 to about 0.6 % by weight.

4. The composition according to claim 1, wherein R^{E} is selected from the group consisting of H, methyl, and ethyl.

5. The composition according to claim 1, wherein the ammonium fluoride comprises a combination of NH₄F and N(CH₃)₄F.

6. The composition according to claim 1, wherein the organic solvent is present in an amount of from 10 to 25 % by weight.

7. The composition according to claim 1, wherein the organic solvent is selected from the group consisting of dimethyl sulfoxide, tetrahydrothiophen-1,1-dioxide (sulfolane), ethyl methyl sulfone, and ethyl isopropyl sulfone.

8. The composition according to claim 1, wherein the pH of the composition is from 2 to 6, .

9. The composition according to claim 1, further comprising a surfactant selected from the group consisting of a C₆ to C₃₀ aliphatic amine, a C₆ to C₂₀ aliphatic carboxylic acid, and a combination thereof.

10. The composition according to claim 1, comprising or consisting essentially of
(a) 0.01 to 0.3 % by weight HF;
(b) 0.1 to 1% by weight of the ammonium fluoride of formula NR^{E}₄F, wherein R^{E} is H, methyl, or ethyl;
(c) 5 to 30 % by weight of the organic solvent;
(d) 70 % by weight or more water;
(e) optionally 0.05 to 0.5 % by weight of an ammonium compound selected from the group consisting of ammonia and a C₄ to C₂₀ quaternized aliphatic ammonium; and
(f) optionally 0.001 to 1% by weight of a surfactant selected from the group consisting of a C₆ to C₂₀ aliphatic amine, a C₆ to C₂₀ aliphatic acid, and a combination thereof.

11. The composition according to claim 1, comprising or consisting essentially of
(a) 0.01 to 0.1 % by weight HF;
(b) 0.1 to 0.6 % by weight of the ammonium fluoride of formula NR^{E}₄F, wherein R^{E} is H, methyl, or ethyl;
(c) 10 to 25 % by weight of the organic solvent;
(d) 74.3 % by weight or more water;
(e) optionally 0.05 to 0.5 % by weight of an ammonium compound selected from the group consisting of ammonia and a C₄ to C₂₀ quaternized aliphatic ammonium; and
(f) optionally 0.001 to 0.5 % by weight of a surfactant selected from the group consisting of a C₆ to C₂₀ aliphatic amine, a C₆ to C₂₀ aliphatic acid, and a combination thereof.

12. The composition according to claim 1, comprising or consisting essentially of
(a) 0.001 to 0.1 % by weight HF;
(b) 0.1 to 0.6 % by weight of the ammonium fluoride of formula NR^{E}₄F, wherein R^{E} is H, methyl, or ethyl;
(c) 12 to 23 % by weight of the organic solvent;
(d) 76.3 % by weight or more water;
(e) optionally 0.05 to 0.3 % by weight of an ammonium compound selected from the group consisting of ammonia and a C₄ to C₂₀ quaternized aliphatic ammonium; and
(f) 0.005 to 0.1 % by weight of a surfactant selected from the group consisting of a C₆ to C₂₀ aliphatic amine, a C₆ to C₂₀ aliphatic acid, and a combination thereof.

13. A method of using the composition according to claim 1, the method comprising using the composition for removing post-etch residues in the presence of a layer comprising silicon and a dielectric layer comprising a silicon oxide.

14. A process of removing post-etch residues in the presence of a silicon layer comprising silicon and a dielectric layer comprising a silicon oxide, the process comprising:
(a) providing a microelectronic device comprising a surface that comprises the post-etch residues, the silicon layer, and the dielectric layer,
(b) providing a composition according to claim 1, and
(c) contacting the surface with the composition for a time and at a temperature effective to remove the post-etch residues without damaging the silicon layer and the dielectric layer.

15. The process according to claim 14, before step (a) further comprising:
(a1) dry etching the silicon layer to form recesses in the silicon layer through a photoresist located on top of the parts of the silicon layer not to be dry etched, and
(a2) removing the photoresist.

16. The composition according to claim 1, wherein the organic solvent is present in an amount of from 12 to 23 % by weight.

17. The composition according to claim 1, wherein the pH of the composition is from 3 to 5.
